(19) United States
(12) Patent Application Publication
(10) Pub. No.: US 2013/0278300 A1
(43) Pub. Date: Oct. 24, 2013

(54) MOSFET SWITCH GATE DRIVE, MOSFET SWITCH SYSTEM AND METHOD

(71) Applicants: Reynaldo P. Domingo, Spring, TX (US); Mohamed Amin Bemat, Cypress, TX (US)

(72) Inventors: Reynaldo P. Domingo, Spring, TX (US); Mohamed Amin Bemat, Cypress, TX (US)

(21) Appl. No.: 13/995,436

(22) PCT Filed: Dec. 22, 2010
(86) PCT No.: PCT/US2010/061904

§ 371 Date: Jun. 18, 2013

(51) Int. Cl. H03K 17/30

(52) U.S. Cl. CPC H03K 17/302
USPC 327/109

(57) ABSTRACT

A gate driver (100), a high-side MOSFET switch system (200) and a method (300) of pulse-driven switching a MOSFET employ a Miller capacitance or a Miller capacitance threshold. The gate driver (100) includes a gate discharge portion (110) to provide a first voltage for a first time period to a gate of a MOSFET (102). The first voltage is less than a turn-on threshold voltage of the MOSFET. The gate driver further includes a gate charge portion (120) to provide a second voltage for a second time period to the MOSFET gate. The second voltage is greater than the MOSFET turn-on threshold voltage. The second time period is less than a time period for a gate-source voltage of the MOSFET to exceed the Miller capacitance threshold. The method (300) of pulse-driven switching of a MOSFET includes applying (310) the first voltage for the first time period and applying (320) the second voltage for the second time period.

### CROSS-REFERENCE TO RELATED APPLICATIONS

N/A

### STATEMENT REGARDING FEDERALLY SPONSORED RESEARCH OR DEVELOPMENT

N/A

### BACKGROUND

Modern electrical and electronic systems generally comprise one or more devices, components, and subsystems that are connected to a power supply. The power supply provides operational power (e.g., a supply voltage and supply current) to these system elements, often through a system power bus. In many modern systems, the system elements may be, or even must be able to be, connected and disconnected from the power supply while the power supply is energized. Such connecting and disconnecting (i.e., plugging and unplugging) of devices, components and subsystems into the energized power supply or system power bus are often variously referred to as ‘hot-plugging’ or ‘hot-swapping.’ Since it may be either unavoidable during system operation or even required for system operation, the system must be configured to handle hot-swapping or hot-plugging.

The system elements may present a load impedance to the power supply, or equivalently to the system power bus, that is substantially capacitive. For example, many devices, components and subsystems employ relatively large capacitors to filter power received from the power supply. Such devices, components and subsystems with substantially capacitive load impedances may be referred to as ‘capacitive loads.’ Unfortunately, capacitive loads may present a problem to the system when such capacitive loads are abruptly connected to an energized power supply.

In particular, abrupt connection of the capacitive load to the energized power supply may result in a large current flowing from the power supply to the capacitive load for a short time after the connection is made. For example, when a subsystem (e.g., a blade server) is plugged into the system chassis with system power supply turned ON, a large current may flow into the subsystem as the system power supply capacitive load charges to the supply voltage level. The large current that flows or that may flow immediately after the capacitive load is connected to the energized power supply is often referred to as an ‘inrush current.’ In many systems that require or benefit from hot-swapping or hot-plugging, it may not be possible to avoid situations that have the potential to produce large inrush currents.

A variety of approaches have been developed to address the issues associated with inrush currents associated with providing system power to capacitive loads. For example, a metal-oxide field effect transistor (MOSFET) may be used to control the current between the power supply and the device, component or subsystem. The MOSFET may be controlled to operate in a resistive mode to restrict or limit current. In some instances, a feedback circuit may monitor the current allowing a direct current (DC) voltage level applied to the MOSFET to be adjusted to further control the inrush current. Unfortunately, these approaches may be complicated and costly to implement, may present relatively higher failure probabilities and may subject components used in the power supply and power bus to high power dissipation conditions. For example, operating the MOSFET in a resistive mode may subject the MOSFET to relative high temperatures requiring the use a relatively higher power MOSFET simply to accommodate the inrush currents associated with hot-swapped system elements.

### BRIEF DESCRIPTION OF THE DRAWINGS

The various features of examples may be more readily understood with reference to the following detailed description taken in conjunction with the accompanying drawings, where like reference numerals designate like structural elements, and in which:

FIG. 1 illustrates a plot of switching waveforms in terms of voltages and currents in an example MOSFET, according to an example in accordance with the principles described herein.

FIG. 2 illustrates a block diagram of a gate driver for a MOSFET switch, according to an example in accordance with the principles described herein.

FIG. 3A illustrates a waveform of a pulsed gate voltage, according to an example in accordance with the principles described herein.

FIG. 3B illustrates a waveform of a drive signal used by the gate driver of FIG. 2 to produce the pulsed gate voltage illustrated in FIG. 3A, according to an example in accordance with the principles described herein.

FIG. 4 illustrates a schematic of a high-side MOSFET switch system, according to an example in accordance with the principles described herein.

FIG. 5 illustrates a flow chart of a method of pulse-driven switching of a MOSFET, according to an example in accordance with the principles described herein.

Certain examples have other features that are one of in addition to and in lieu of the features illustrated in the above-referenced figures. These and other features are detailed below with reference to the preceding drawings.

### DETAILED DESCRIPTION

Examples in accordance with the principles described herein control power delivered from a power supply to a capacitive load through or using a MOSFET switch. In particular, according to various examples, an inrush current associated with power delivery is controlled or limited using the MOSFET switch. The inrush current is limited during a start-up phase of power delivery following either a command to turn on the MOSFET switch or an event in which the capacitive load is initially connected to the MOSFET switch (e.g., during hot-swapping or hot-plugging of the capacitive load). Various examples described herein facilitate inrush current control using a pulsed gate voltage applied to a MOSFET of the MOSFET switch. Moreover, the pulsed gate voltage is configured to switch the MOSFET ON and OFF within in a linear region below a threshold above which a Miller capacitance of the MOSFET is fully charged. Doing so may substantially prevent the MOSFET from sourcing large (e.g., potentially damaging) amounts of inrush current to the capacitive load during the start-up phase.

Herein a ‘MOSFET’ is defined as a metal-oxide semiconductor field effect transistor. MOSFET may be either a P-channel MOSFET or an N-channel MOSFET. P-channel MOSFETs generally differ from N-channel MOSFETs in a polarity of various voltages (e.g., gate-source voltage). As such, an N-channel MOSFET is described herein by way of example and without loss of generality. In particular, the block diagrams, circuits and associated discussion provided below may be readily adapted to either N-channel or P-channel MOSFETs by appropriate changes in the polarity (e.g., ‘−’ to ‘+’ or ‘+’ to ‘−’) of various voltages.

The MOSFET is a three terminal device having a drain, a source and a gate. A voltage applied to the gate (e.g., a gate voltage) may be used to control or modulate a conduction channel between the drain and the source. In turn, the control or modulation controls current that may flow between the drain and the source through the conduction channel. For example, The MOSFET may be used as a switch to control power being delivered from a power source to a load under control of the gate voltage. The power is delivered by an electric current flowing through the MOSFET under control of the gate voltage, for example.

Further, as defined herein, the MOSFET is an enhancement mode MOSFET. An enhancement mode MOSFET is ‘OFF’ or in an off state (i.e., conducts no current or conducts an insubstantial amount of current between the source and the drain) in the absence of a gate voltage. The application of the gate voltage directly forms the conduction channel. Once formed, the channel facilitates the flow of current between the drain and the source.

The MOSFET, as described herein, exhibits operational characteristics that generally may comprise two thresholds. A first threshold is the so-called ‘turn-on’ threshold that is generally defined in terms of a turn-on threshold voltage Vₜₕ. The turn-on threshold voltage Vₜₕ is a voltage between the gate and the source of the MOSFET at which the conduction channel (hereinafter ‘channel’) forms between the drain and the source. A second threshold is defined herein as a Miller capacitance threshold and is characterized in terms of a Miller capacitance threshold voltage V_{th-MC}. The Miller capacitance threshold is a threshold at which the Miller capacitance of the MOSFET (i.e., a capacitance between gate and drain) begins to be charged as the MOSFET starts to turn ON fully. The Miller capacitance threshold is typified by a substantial drop in a voltage across the drain and source of the MOSFET (V_{DS}) and generally defines a point above which a current the MOSFET channel between the drain and source substantially reaches or approaches a maximum or ‘flat’ level. The channel current above the Miller capacitance threshold is typically limited only by the drain-to-source channel resistance and a circuit impedance in which the MOSFET is used.

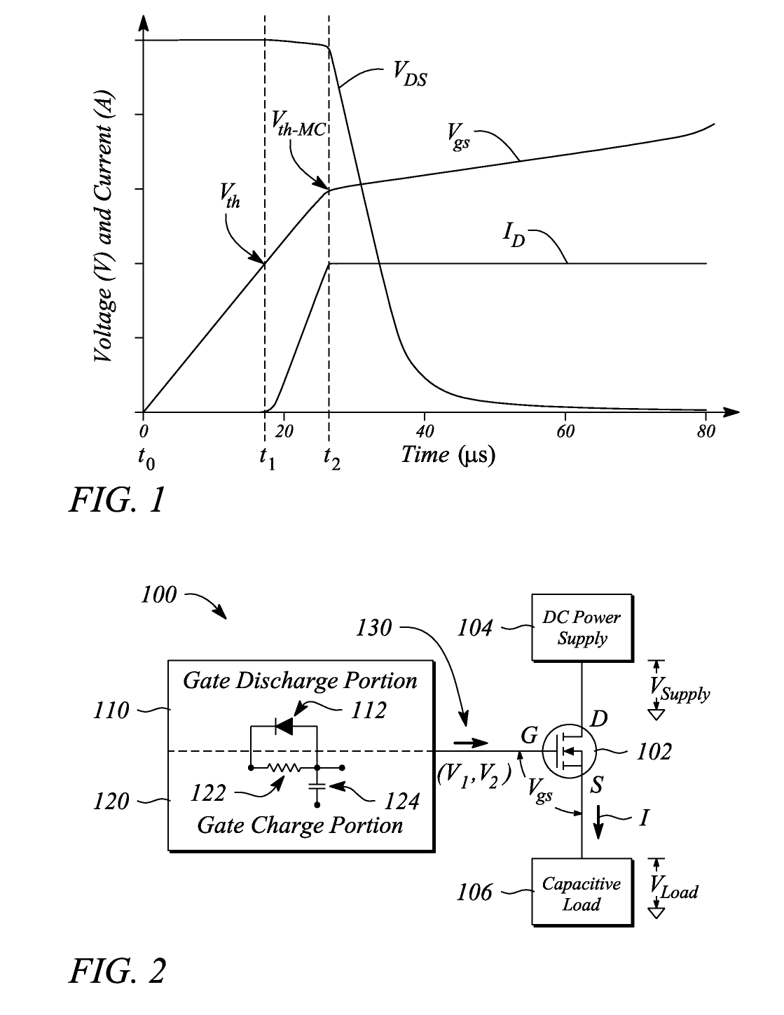

FIG. 1 illustrates a plot of switching waveforms in terms of voltages and currents in an example MOSFET, according to an example of the principles described herein. In particular, FIG. 1 illustrates an applied gate-source voltage V_{gs}, a drain-source voltage V_{DS}, and a drain current I_{D} of the example MOSFET as a function of time t. Also illustrated are the turn-on threshold voltage Vₜₕ and the Miller capacitance threshold voltage V_{th-MC}. FIG. 1 further serves to define the Miller capacitance threshold voltage V_{th-MC} in accordance with the principles described herein.

Referring to FIG. 1, as a voltage is applied to the example MOSFET gate, the gate-source voltage V_{gs} begins to rise (e.g., between time t₀ and t₁). When the turn-on threshold voltage Vₜₕ is reached (i.e., see time t₁), the channel forms between the drain and the source of the example MOSFET and a drain current I_{D} begins to flow in the channel, as illustrated (i.e., I_{D}>0 after t₁). As the applied gate-source voltage V_{gs} continues to increase, the drain current I_{D} increases in a substantially linear manner relative to the applied gate-source voltage V_{gs}. In conjunction with the substantially linear increase in the drain current I_{D}, the drain-source voltage V_{DS} begins to drop, as illustrated. However (as illustrated in FIG. 1), the drop in the drain-source voltage V_{DS} is relatively minor (e.g., less than about a few percent of the value) before t₁.

As the applied gate-source voltage V_{gs} continues to rise even further, the Miller capacitance threshold voltage V_{th-MC} defining the Miller capacitance threshold is eventually reached at time t₂. Above the Miller capacitance threshold voltage V_{th-MC} the drain current is maximized, limited only by its channel (drain-to-source) resistance relative to the applied gate-source voltage V_{gs}, as is illustrated. In fact, the drain current I_{D} becomes substantially saturated at or near a maximum level (e.g., I_{D}˜constant). In addition, above the Miller capacitance threshold voltage V_{th-MC} (i.e., at and after t₂) the drain-source voltage V_{DS} drops rapidly. The Miller capacitance threshold voltage V_{th-MC} may be readily and immediately identified for a given MOSFET by this concomitant drain-source voltage V_{DS} drop and linear-to-saturated drain current I_{D} characteristic illustrated in FIG. 1 after time t₂.

Further, as used herein, the article ‘a’ is intended to have its ordinary meaning in the patent arts, namely ‘one or more’. For example, ‘a MOSFET’ means one or more MOSFETs and as such, ‘the MOSFET’ means ‘the MOSFET(s)’ herein. Also, any reference herein to ‘top’, ‘bottom’, ‘upper’, ‘lower’, ‘up’, ‘down’, ‘front’, back’, ‘left’ or ‘right’ is not intended to be a limitation herein. Herein, the term ‘about’ when applied to a value generally means plus or minus 10% unless otherwise expressly specified. Moreover, examples herein are intended to be illustrative only and are presented for discussion purposes and not by way of limitation.

FIG. 2 illustrates a block diagram of a gate driver 100 for a MOSFET switch, according to an example of the principles described herein. The gate driver 100 is configured to control a MOSFET 102 connected between a direct current (DC) power supply 104 and a capacitive load 106. For example, the MOSFET 102 may be an N-channel MOSFET as illustrated in FIG. 2 having a drain D connected to the DC power supply 104 and a source S connected to the capacitive load 106. The MOSFET 102 acts to switch (i.e., a MOSFET switch) a current and a voltage produced by the DC power supply 104 and provided through the MOSFET 102 to the capacitive load 106. In other examples (not illustrated), the MOSFET may comprise a P-channel MOSFET. In yet other examples (not illustrated), the MOSFET may comprise a plurality of MOSFETs connected in parallel at respective ones of their drains, sources and gates.

The gate driver 100 is connected to a gate G of the MOSFET 102, as illustrated in FIG. 2. The gate driver 100 controls an inrush current I delivered from the DC power supply 104 to the capacitive load 106. The controlled inrush current I may facilitate hot-swapping of the capacitive load, for example. Specifically, the inrush current I may be controlled to be below a peak current level that may cause damage to one or more of the MOSFET 102, the DC power supply 104, and the capacitive load 106 when the capacitive load 106 is abruptly connected to an energized DC power supply 106 by way of the MOSFET 102 (i.e., a hot-swap connection), for example.

The gate driver 100 for a MOSFET switch comprises a gate discharge portion 110. The gate discharge portion 110 is configured to provide a first voltage V₁ for a first time period T₁ to the gate G of the MOSFET 102. The first voltage V₁ provided by the gate discharge portion 110 is less than a turn-on threshold voltage Vₜₕ of the MOSFET 102. For example, the gate discharge portion 110 may be connected to and provide the first voltage V₁ through a connection of the gate driver 100 to the gate G of the MOSFET 102, as illustrated in FIG. 2.

By ‘less than,’ with respect to the first voltage V₁ and the turn-on threshold voltage Vₜₕ herein, it is meant by definition that the first voltage V₁ has a magnitude that is less than the turn-on threshold voltage Vₜₕ of the MOSFET 102. For example, the first voltage V₁ may be about zero volts (V) relative to a voltage Vₛ at the source S of the MOSFET 102 (i.e., V₁ is about 0 V). In another example, the first voltage V₁ may be less than about 2 V (i.e., V₁ is about 2 V) relative to the source voltage Vₛ of the MOSFET 102 when the turn-on threshold voltage Vₜₕ is about 2V for an N-channel MOSFET 102, as illustrated in FIG. 2.

The gate driver 100 for a MOSFET switch further comprises a gate charge portion 120. The gate charge portion 120 is configured to provide a second voltage V₂ for a second time period T₂. For example, the gate charge portion 120 may be connected to and provide the second voltage V₂ through a connection between the gate driver 100 to the gate G of the MOSFET 102. The second voltage V₂ provided by the gate charge portion 120 is greater than the MOSFET turn-on threshold voltage Vₜₕ. Further, the second period of time T₂ is less than a time period for a gate-source voltage V_{gs} of the MOSFET 102 to exceed a Miller capacitance threshold voltage V_{th-MC}.

For example, the second voltage V₂ may be greater than about 2 V (e.g., 3-6 V) relative to a voltage Vₛ at the source S of the MOSFET 102 when the turn-on threshold voltage Vₜₕ of the N-channel MOSFET 102 is about 2 V. In another example, the second voltage V₂ may be close to a voltage that is applied to place the MOSFET 102 at an onset of a completely ON condition. An exact value of the second voltage V₂ generally may not exceed the V_{th-MC} so that a peak current is substantially limited to a safe level during the portion of the second time period T₂.

In operation, given the above-defined characteristics of the gate driver 100, when the first voltage V₁ provided by the gate discharge portion 110 is applied to the gate G, the gate-source voltage V_{gs} of the MOSFET 102 drops in magnitude or is said to be ‘discharged.’ As the gate-source voltage V_{gs} drops below the turn-on threshold voltage Vₜₕ of the MOSFET 102 (e.g., due to being discharged), the MOSFET 102 substantially ceases to conduct current from the drain D to the source S and is said to be ‘OFF’ or ‘turned OFF.’ Likewise, when the second voltage V₂ provided by the gate charge portion 120 is applied to the gate G, the gate-source voltage V_{gs} of the MOSFET 102 rises in magnitude or is said to be ‘charged.’ As the gate-source voltage V_{gs} exceeds (in magnitude) the turn-on threshold voltage Vₜₕ of the MOSFET 102 (e.g., due to being charged), the MOSFET 102 substantially begins to conduct current from the drain D to the source S and is said to be ‘ON’ or ‘turned ON.’ However, as long as the gate-source voltage V_{gs} of the MOSFET 102 remains below the Miller capacitance threshold voltage V_{th-MC}, an amount or level of current that can flow through the MOSFET 102 is restricted, as is discussed above. If the second time period T₂ is selected to be short enough that the Miller capacitance threshold voltage V_{th-MC} is not exceeded, then the current flowing through the MOSFET 102 remains limited throughout the second time period T₂.

Further during operation, the gate discharge portion 110 and the gate charge portion 120 generally cooperate in their respective operational modes. In particular, the gate driver 100 is configured to provide a substantially pulsed gate voltage 130. The pulsed gate voltage 130 produced by the gate driver 100 alternates between the first voltage V₁ for the first time period T₁ and the second voltage V₂ for the second time period T₂.

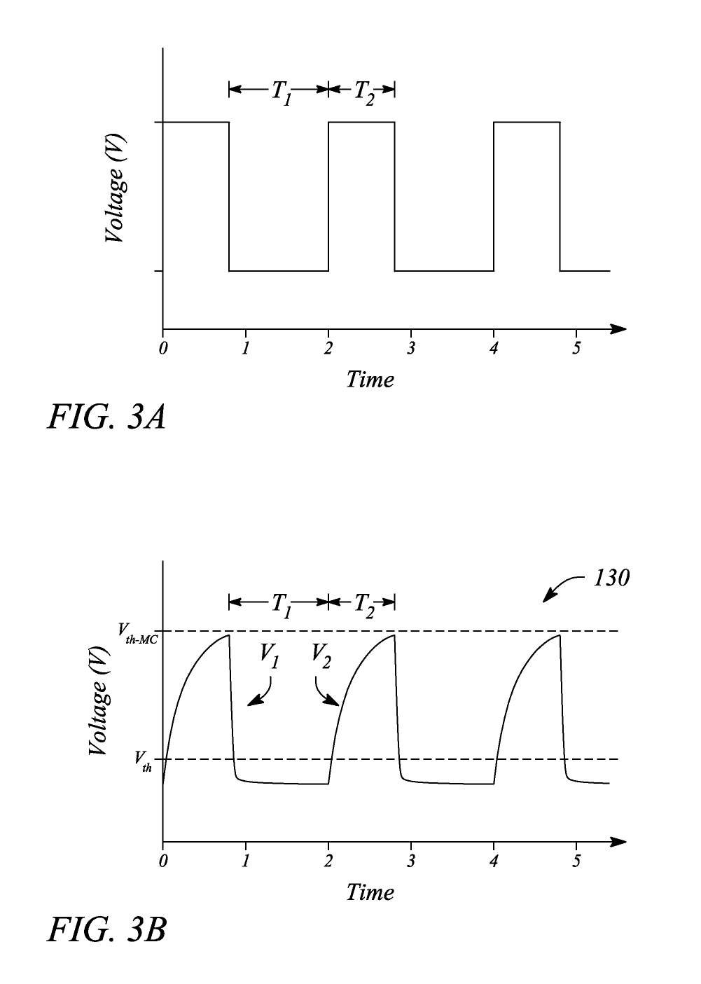

FIG. 3A illustrates a waveform of the pulsed gate voltage 130, according to an example of the principles described herein. FIG. 3B illustrates a waveform of a drive signal used by the gate driver 100 of FIG. 2 to produce the pulsed gate voltage 130 illustrated in FIG. 3A, according to an example of the principles described herein. In particular, FIG. 3B illustrates a pulsed waveform of the drive signal. The pulsed waveform illustrates a duty cycle of the pulsed gate voltage 130 in terms of the first time period T₁ and the second time period T₂. The pulsed waveform illustrated in FIG. 3B may be applied to the gate driver 100 in some examples. In other examples, the pulsed waveform illustrated in FIG. 3B is generated by the gate driver 100. In yet other examples, the pulsed waveform illustrated in FIG. 3B is implicit in the operation of the gate driver. FIG. 3A illustrates a difference between a rise time and a fall time of the pulsed gate voltage 130, according to some examples.

In some examples, the duty cycle of the second time period T₂ alternating with the first time period T₁ is less than about 50 percent. For example, the duty cycle may be between about 30 percent and about 40 percent. For example, as illustrated in FIGS. 3A and 3B, the pulsed gate voltage 130 has a duty cycle of about 40 percent. In some examples, the duty cycle is less than about 20 percent. In yet other examples, the duty cycle may be less than about 10 percent, or less than about 5 percent.

Referring again to FIG. 2, the gate charge portion 120 comprises a series resistor 122 and a shunt capacitor 124, in some examples. An R-C time constant of the series resistor 122 and the shunt capacitor 124 establishes a rise time of the second voltage V₂. The rise time of the second voltage V₂, in turn, establishes a rise time of the MOSFET gate-source voltage V_{gs} during the second time period T₂. In some examples, a capacitance of the shunt capacitor 124 may be between 10 and 20 times greater than a gate capacitance of the MOSFET 102. For example, the shunt capacitance may be 15 times the gate capacitance. Selecting the shunt capacitance to be much larger (e.g., 10-20 time larger) than the gate capacitance allows the capacitance of the shunt capacitor 124 to substantially dominate the gate capacitance and thus, dictate the rise time of the gate-source voltage V_{gs} during the second time period T₂. Selection of a specific resistance of the series resistor 122 depends, in turn, on the desired rise time and the selected capacitance. According to some examples, the resistance of the series resistor 122 may be between about 500 Ohms (Ω) and about 10 kilo Ohms (kΩ). For example, the series resistor 122 may have about a 2 kΩ resistance when the shunt capacitor 124 has a capacitance of about 4.7 nano Farad (nF).

In some examples, the gate discharge portion 110 comprises a diode 112 in parallel with the series resistor 122 of the gate charge portion 120. The diode 112 is configured to provide a discharge path for current during the first time period T₁. The discharge path facilitates a fall time of the MOSFET gate-source voltage V_{gs} during the first time period T₁ that is less than the rise time produced by the gate charge portion 120.

For example, when the MOSFET 102 is an N-channel MOSFET as illustrated in FIG. 2, a cathode of the diode 112 may be connected to an input of the series resistor 122, while an anode of the diode 112 is connected to an output of the series resistor 122 as well as to the shunt capacitor 124. During the second time period T₂ as the capacitor 124 is charging, the diode 112 is reverse biased and substantially all of the current charging the shunt capacitor 124 flows through the series resistor 122. However, during the first time period T₁ as the capacitor 124 is discharging, the diode 112 is forward biased and conducts a substantial portion of the current such that the series resistor 122 is substantially bypassed.

In some examples, the gate discharge portion 110 further comprises a switch (not illustrated) that connects and disconnects the diode 112 to a voltage (i.e., a ‘below-threshold voltage’) that is below (or less than) the turn-on threshold voltage Vₜₕ of the MOSFET 102. When connected by the switch to the below-threshold voltage, current flowing through the diode 112 discharges the shunt capacitor 124 to provide the first voltage V₁. In such examples, the gate discharge portion 110 may further comprise a voltage source (not illustrated) that provides the below-threshold voltage.

In some examples, the gate charge portion 120 further comprises a switch (not illustrated) that connects and disconnects the series resistor 122 to a voltage (i.e., an ‘above-threshold voltage’) that is above the turn-on threshold Vₜₕ of the MOSFET 102. When connected by the switch to the above-threshold voltage, current flowing through the series resistor 122 charges the shunt capacitor 124 to provide the second voltage V₂. In such examples, the gate charge portion 120 may further comprise a voltage source (not illustrated) that provides the above-threshold voltage. In some examples, the switch may be shared by the gate discharge portion 110 and the gate charge portion 120. For example, during the first time period T₁ the switch may connect the diode 112 and the series resistor 122 to the below-threshold voltage. During the second time period T₂, the switch may connect the diode 112 and the series resistor 124 to the above-threshold voltage, for example.

In various other examples (not illustrated), the gate discharge portion 110 comprises a pulsed or switched voltage source that provides the first voltage V₁ for the first time period T₁. For example, the pulsed or switched voltage source may be connected directly to the gate G of the MOSFET 102. Similarly in various other examples (not illustrated), the gate charge portion 120 comprises a pulsed or switched voltage source that provides the second voltage V₂ for the second time period T₂, wherein the pulsed or switched voltage source is connected directly to the MOSFET gate G. In yet other examples (not illustrated), one or both of the gate-discharge portion 110 and the gate charge portion 120 may comprise a pulsed or switched voltage source and a series resistance. Current flowing through the series resistance to discharge or charge the gate capacitance establishes the respective first voltage V₁ during the first period of time T₁ and the respective second voltage V₂ during the second period of time T₂, for example. In yet other examples, the pulsed or switched voltage source of the gate discharge portion 110 and the gate charge portion 120 may be a pulsed or switched voltage source that is shared between the portions 110, 120.

In some examples, the gate driver 100 ceases to provide a pulsed gate voltage 130 and instead provides a constant gate voltage (not illustrated) when a load voltage V_{load} at the capacitive load 106 is within a predetermined percentage of a supply voltage V_{supply} of the DC power supply 104. In such examples, the constant gate voltage may be high enough to facilitate providing an operational current supply to the capacitive load 106. In other words, the constant gate voltage may be substantially above the Miller capacitance threshold voltage V_{th-MC}, for example, such that the MOSFET 102 is in a complete or at least substantially complete ‘ON’ state. In some examples, the constant gate voltage is provided when the load voltage V_{load} has risen to within about 5 percent of the supply voltage V_{supply}. In another example, the constant gate voltage is provided when there is less than about a 10 percent difference between the load voltage V_{load} and the supply voltage V_{supply}. In yet other examples, another percentage difference ranging from about 1 percent to about 30 percent may be employed to provide the constant gate voltage.

In some examples the gate charge portion 120 is further configured to provide the constant gate voltage. For example, when the load voltage V_{load} has risen to within a predetermined percent of the supply voltage V_{supply}, the gate charge portion 120 may cease pulsing and provide the constant voltage to the MOSFET gate G.

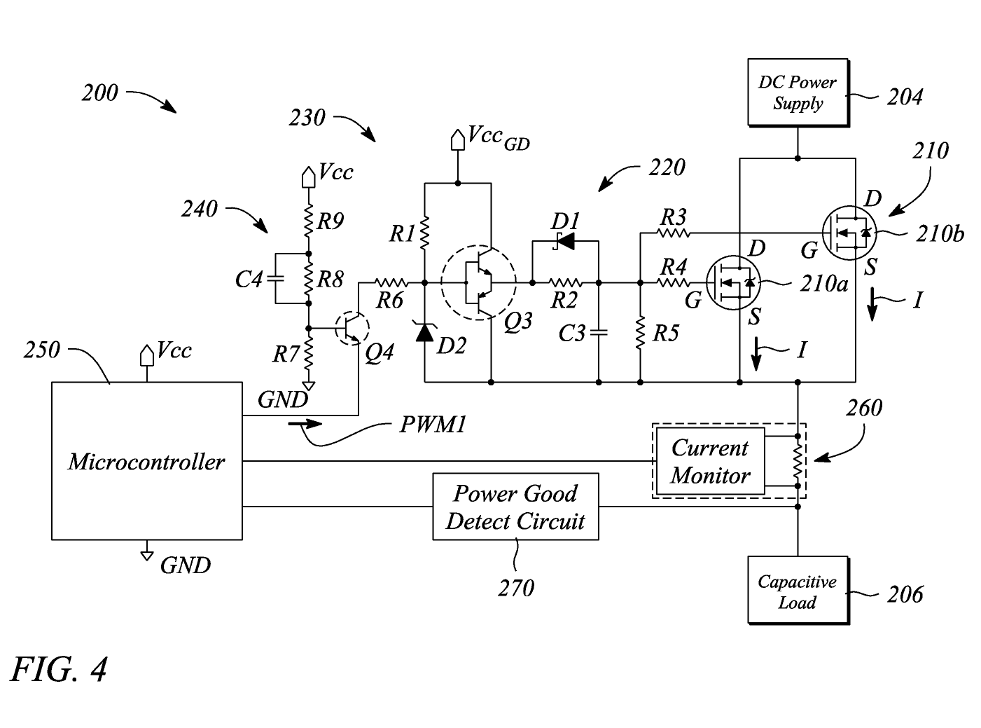

FIG. 4 illustrates a schematic of a high-side MOSFET switch system 200, according to an example of the principles described herein. The high-side MOSFET switch system 200 provides a supply voltage V_{supply} produced by a direct current (DC) power supply 204 to a capacitive load 206. Further, the high-side MOSFET switch system 200 controls an inrush current from the DC power supply 204 to the capacitive load 206. In some examples, the high-side MOSFET switch system 200 is substantially similar to the gate driver 100 and associated MOSFET 102, described above. In particular, the high-side MOSFET switch system 200 may facilitate hot-swapping of the capacitive load 206. The high-side MOSFET switch system 200 may also be used to turn OFF power (voltage and current) to the capacitive load 206.

The high-side MOSFET switch system 200 comprises a MOSFET 210. The MOSFET 210 is connected to provide power from the DC power supply 204 to the capacitive load 206. As illustrated, the MOSFET 210 comprises an N-channel MOSFET by way of example. Further, the MOSFET 210 has a drain D connected to the DC power supply 204 and a source S connected to the capacitive load 206. One or both of these connections may be broken during a hot-swap, for example.

In some examples, the MOSFET 210 may comprise a plurality of either P-channel or N-channel MOSFETs connected in parallel. As illustrated by way of example in FIG. 4, the MOSFET 210 comprises a pair of N-channel MOSFETs 210a, 210b connected in parallel between the DC power supply 204 and the capacitive load 206. A drain D of each of the parallel-connected MOSFETs 210a, 210b of the pair is connected to the DC power supply 204. Similarly, a source S of each of the parallel-connected MOSFETs 210a, 210b of the pair is connected to the capacitive load 206, as illustrated.

The high-side MOSFET switch system 200 further comprises a gate drive circuit 220. The gate drive circuit 220 is connected to a gate G of the MOSFET 210, as illustrated. Specifically, the gate drive circuit 220 is connected to a gate G of the each of the N-channel MOSFETs 210a, 210b of the pair, as illustrated by way of example. The connection is made through a pair of series resistors R3, R4. The pair of series resistors R3, R4 may help to balance current flowing into respective ones of the pair of parallel-connected MOSFETs 210a, 210b, for example. A shunt resistor R5 at an input of the pair of series resistors R3, R4 provides a high resistance (e.g., 100 kΩ) discharge path for a gate-source voltage V_{gs} of the MOSFET 210. Since the following discussion applies equally to examples having one MOSFET 210 as well as to examples comprising a plurality of parallel-connected MOSFETs (e.g., 210a, 210b), reference below is made to the MOSFET 210 with the understanding that the MOSFET 210 explicitly means ‘one or more MOSFETs connected in parallel with associated series resistors (e.g., R3, R4)’.

The gate drive circuit 220 is configured to provide a pulsed gate voltage to the gate G of the MOSFET 210. The pulsed gate voltage has a first voltage V₁ for a first time period T₁ and a second voltage V₂ for a second time period T₂. The first voltage V₁ is less than a turn-on threshold gate-source voltage Vₜₕ of the MOSFET 210. The second voltage V₂ is greater than the turn-on threshold gate-source voltage Vₜₕ. Further, the second time period T₂ is less than a time period for the gate-source voltage V_{gs} of the MOSFET 210 to exceed a second threshold voltage at which a Miller capacitance of the MOSFET 210 is charged (i.e., the Miller capacitance threshold voltage V_{th-MC}). In some examples, the gate drive circuit 220 is substantially similar to the gate driver 100, described above.

According to some examples (e.g., as illustrated), the gate drive circuit 220 comprises a series resistor R2 and a shunt capacitor C3. The pulsed gate voltage is substantially a voltage across the shunt capacitor C3. The series resistor R2 and the shunt capacitor C3 may be substantially similar to the series resistor 122 and the shunt capacitor 124 of the gate charge portion 120 described above with respect to the gate driver 100, in some examples. In particular, the shunt capacitor C3 has a capacitance that is generally greater than a gate capacitance of the MOSFET 210 so that the capacitance of the shunt capacitor C3 substantially dominates the gate capacitance, and in conjunction with the series resistor R2, establishes a rise time of the second voltage V₂ during the second time period T₂.

For example, the capacitance of the shunt capacitor C3 may be between about 10 and about 20 times greater than the gate capacitance of the MOSFET 210 (or a combined gate capacitance of a plurality of parallel-connected MOSFETs, e.g., 210a, 210b). As is discussed above with respect to the series resistor 122, the series resistor R2 has a resistance that, along with the capacitance of the shunt capacitor C3, provides an R-C time constant that substantially establishes the rise time of the second voltage V₂. In some examples, the resistance of the series resistor R2 is between about 1 kΩ and about 10 kΩ. The series resistor R2 may have a resistance of about 2 kΩ when the capacitance of the shunt capacitor C3 is about 4.7 nF, for example.

According to some examples (e.g., as illustrated), the gate drive circuit 220 further comprises a diode D1. The diode D1 is connected in parallel with the series resistor R2. The diode D1 may be substantially similar to the diode 112 of the gate discharge portion 110 described above with respect to the gate driver 100, according to some examples. In particular, an anode of the diode D1 is connected to the shunt capacitor C3 while a cathode of the diode D1 is connected to an input of the series resistor R2, as illustrated in FIG. 4. In some examples, the diode D1 is configured to provide a discharge path for current during the first time period T₁ that facilitates a fall time of the MOSFET gate-source voltage V_{gs} that is less than the rise time. In some examples, the fall time is substantially less than the rise time (e.g., substantially instantaneous) due to a low forward bias resistance of the diode D1.

As illustrated, the gate drive circuit 220 further comprises a switched voltage source 230, according to some examples. The switched voltage source 230 provides a switched voltage to the input of the series resistor R2 and the cathode of the diode D1 to produce the first and second voltages V₁, V₂ at the shunt capacitor C3. The switched voltage source 230 may be substantially similar to the switched voltage source described above with respect to the gate driver 100. In particular, the switched voltage source 230 provides a pulsed or switched voltage having a first state that establishes the first voltage V₁ and a second state that establishes the second voltage V₂.

In the example illustrated in FIG. 4, the switched voltage source 230 comprises a totem-pole connected bipolar transistor pair Q3. A collector of an NPN transistor of the bipolar transistor pair Q3 is connected to a gate drive voltage Vcc_{GD}. The gate drive voltage Vcc_{GD} is generally higher than the voltage of the DC power source 204 when the MOSFET 210 is an N-channel MOSFET, for example. The gate drive voltage Vcc_{GD} may be derived from the DC power source 204 using a charge pump circuit (not illustrated), for example. An emitter of the NPN transistor and an emitter of a PNP transistor of the bipolar transistor pair Q3 are both connected to the input of the series resistor R2 and the cathode of the diode D1. The NPN-PNP emitters of the bipolar transistor pair Q3 provide the switched voltage that produces the first and second voltages V₁, V₂, described above. A base of the NPN transistor and a base of the PNP transistor are connected through a bias resistor R1 to the gate drive voltage Vcc_{GD}. The bases of the NPN and PNP transistors are also connected to a cathode of a zener diode D2. An anode of the zener diode D2 is connected the source S of the MOSFET 210.

When reverse biased using the bias resistor R1, the zener diode D2 establishes a fixed voltage (e.g., 6.8 V set by a zener diode level) relative to a voltage at the MOSFET source S at the NPN-PNP bases. The fixed voltage turns ON the NPN transistor and simultaneously turns OFF the PNP transistor. This allows the NPN transistor to source current from the gate drive voltage Vcc_{GD} through the series resistor R2 to charge the shunt capacitor C3 and produce the second voltage V₂. Alternatively, when the NPN-PNP bases are driven to a low state that substantially turns OFF the NPN transistor and turns ON the PNP transistor, a voltage at the input of the series resistor R2 drops to the voltage of the MOSFET source S. With the PNP transistor turned ON, the shunt capacitor C3 discharges through the diode D1 yielding the first voltage V₁.

As illustrated, the NPN and PNP transistors are driven by a pulse width modulated (PWM1) signal that is translated through a level-shift circuit 240, for example. The translated PWM1 signal alternately facilitates reverse biasing the zener diode D2 and setting the low state at the NPN-PNP bases. The PWM1 signal may have a waveform substantially similar to the waveform illustrated in FIG. 3A, according to some examples. For example, the PWM1 signal may be a signal that alternates between about 0 V and about 5V that is produced by a microcontroller 250. In another example, another pulse-producing circuit such as an LM555 timer (not illustrated) may be used to provide the PWM1 signal. In addition, other voltage levels besides about 0 V and about 5 V may be employed in the PWM1 signal, without departing from the scope described herein. The PWM1 signal further establishes the duty cycle of first and second voltages V₁, V₂, for example.

In some examples, the level-shift circuit 240 may comprise an NPN transistor Q4 having a collector connected through a resistor R6 (e.g., about 10Ω) to the bases of the NPN and PNP transistors of the bipolar transistor pair Q3 (e.g., as illustrated). An emitter of the NPN transistor Q4 is driven by the PWM1 signal. A base of the NPN transistor Q4 is biased such that the NPN transistor Q4 is turned ON when the PWM1 signal is in a low state (e.g., about 0 V) and turned OFF when the PWM1 signal is in a high state (e.g., about 5V). When the NPN transistor Q4 is OFF, the zener diode D2 is reverse biased and a voltage at the bases of the NPN and PNP transistors of the bipolar transistor pair Q3 is established by the zener diode D2. On the other hand, when the NPN transistor Q4 is ON, the voltage at the bases of the NPN and PNP transistors of the bipolar transistor pair Q3 is pulled down to the low state of the bases (e.g., about 0 V).

Biasing of the NPN transistor Q4 may be provided by a bias network, as illustrated by way of example in FIG. 4. The example bias network is connected between the NPN transistor Q4 base and a supply voltage Vcc (e.g., a supply voltage of the microcontroller 250). The example bias network comprises a shunt resistor R7 (e.g., about 10 kΩ) connected between the NPN transistor Q4 base and a ground potential (GND). The bias network further comprises a resistor R8 (e.g., about 6.8 kΩ) and a resistor R9 (e.g., about 100Ω) connected in series between the NPN transistor Q4 base and the supply voltage Vcc. The bias network further comprises a capacitor C4 (e.g., about 0.1 μF) connected in parallel with the resistor R8. As illustrated, the bias network is a voltage divider that produces a bias voltage (Vbias) at the NPN transistor Q4 base that is the supply voltage Vcc multiplied by a resistance of the shunt resistor R7 and divided by a resistive sum of the resistors R7, R8 and R9 (i.e., Vbias=Vcc*R7/(R8+R9+R7)).

In some examples, the high-side MOSFET switch system 200 may further comprise the microcontroller 250, a current monitor 260, and a power good detect circuit 270, as illustrated in FIG. 4 by way of example. As discussed above, the microcontroller 250 provides the PWM1 signal to the high-side MOSFET switch system 200, according to some examples. In some examples, the microcontroller 250 may generate a second pulsed signal used to implement the charge pump circuit (not illustrated) that may be used to provide the gate drive voltage Vcc_{GD}. The microcontroller 250 may be substantially any microcontroller or microprocessor, for example.

The current monitor 260 monitors a current flowing to the capacitive load 206. The current monitor 260 reports a result of monitoring the current to the microcontroller 250, according to some examples. In some examples, the reported results are used to detect a short circuit condition in the capacitive load 206. When a short circuit condition is detected, the microcontroller 250 may shut down the high-side MOSFET switch system 200, for example.

The power good detect circuit 270 monitors a voltage level of the power supplied to the capacitive load 206. The power good detect circuit 270 may be used to detect when a voltage at the capacitive load 206 has reached a predetermined percentage of the supply voltage V_{supply}, for example. When the predetermined percentage is reached, the power good detect circuit 270 may signal the microcontroller 250. The microcontroller 250 may respond by discontinuing production of the PWM1 signal and placing the MOSFET 210 in a static ON condition. Alternatively, the power good detect circuit 270 may simply report the voltage at the capacitive load 206 to the microcontroller 250, for example. In this example, the microcontroller 250 implements determining the predetermined percentage.

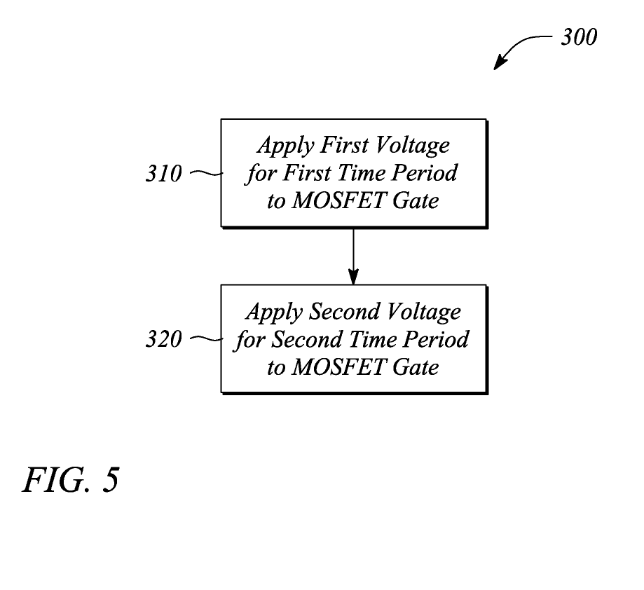

FIG. 5 illustrates a flow chart of a method 300 of pulse-driven switching of a MOSFET, according to an example of the principles described herein. The pulse-driven switching may facilitate using the MOSFET to control inrush current provided to a capacitive load, for example. In particular, the method 300 of pulse-driven switching may be used to implement one or both of a gate driver 100 and a high-side MOSFET switch system 200, as are described above according to some examples.

The method 300 of pulse-driven switching comprises applying 310 a first voltage for a first period of time to a gate of the MOSFET. The first voltage is less than a turn-on threshold voltage of the MOSFET. For example, the first voltage and the first period of time may be substantially similar to the respective first voltage V₁ and the first period of time T₁, described above with respect to either the gate driver 100 or the high-side MOSFET switch system 200.

The method 300 of pulse-driven switching further comprises applying 320 a second voltage for a second period of time to the MOSFET gate. The second voltage is greater than the MOSFET turn-on threshold voltage. The second period of time is less than a time period for a gate-source voltage of the MOSFET to exceed a Miller capacitance threshold voltage. For example, the second voltage and the second period of time may be substantially similar to the respective second voltage V₂ and the second period of time T₂, described above with respect to either the gate driver 100 or the high-side MOSFET switch system 200.

According to various examples, applying 310 the first voltage alternates with applying 320 the second voltage to provide pulse-driven switching of the MOSFET. The pulse-driven switching may control an inrush current provided to the capacitive load by the MOSFET. The inrush current may be provided by a direct current (DC) power source, for example.

In some examples, a duty cycle of the second period of time alternating with the first period of time is less than a predetermined percent. For example, the duty cycle may be less than about 50 percent. In other examples, the duty cycle may be less than about 40 percent, or less than about 20 percent, or less than about 10 percent. In another example, the duty cycle may be more than 50 percent.

In some examples, the MOSFET comprises an N-channel MOSFET. In other examples, the MOSFET comprises a P-channel MOSFET. In some examples, the MOSFET comprises a plurality of MOSFETs connected in parallel between the DC power supply and the capacitive load. For example, the MOSFET may comprise two parallel-connected MOSFETs. In another example, the MOSFET may comprise three, four or more parallel-connected MOSFETs.

Thus, there have been described examples of a gate driver, a high-side MOSFET switch and a method of pulse-driven switching of a MOSFET that control inrush current provided to a capacitive load. It should be understood that the above-described examples are merely illustrative of some of the many specific examples that represent the principles described herein. Clearly, those skilled in the art can readily devise numerous other arrangements without departing from the scope as defined by the following claims.

What is claimed is:

1. A gate driver for a MOSFET switch comprising:
a gate discharge portion to provide a first voltage for a first time period to a gate of a MOSFET, the first voltage being less than a turn-on threshold voltage of the MOSFET; and
a gate charge portion to provide a second voltage for a second time period to the MOSFET gate, the second voltage being greater than the MOSFET turn-on threshold voltage, the second time period being less than a time period for a gate-source voltage of the MOSFET to exceed a Miller capacitance threshold.

2. A MOSFET switch comprising the gate driver of claim 1, the MOSFET switch further comprising the MOSFET, wherein the MOSFET is connected between a capacitive load and a direct current power supply to switch power and control inrush current delivered to the capacitive load.

3. The MOSFET switch of claim 2, wherein the MOSFET comprises an N-channel MOSFET.

4. The MOSFET switch of claim 2, wherein the MOSFET comprises a plurality of MOSFETs connected in parallel between the direct current power supply and the capacitive load.

5. The gate driver of claim 1, wherein a duty cycle of the second time period alternating with the first time period is less than about 20 percent.

6. The gate driver of claim 1, wherein the gate charge portion comprises a series resistor and a shunt capacitor to establish a rise time of the MOSFET gate-source voltage during the second time period.

7. The gate driver of claim 6, wherein the shunt capacitor has a capacitance that is greater than about 15 times a gate capacitance of the MOSFET.

8. The gate driver of claim 6, wherein the gate discharge portion comprises a diode in parallel with the series resistor of the gate charge portion to provide a discharge path for current during the first time period, the discharge path facilitating a fall time of the MOSFET gate-source voltage during the first time period that is less than the rise time.

9. The gate driver of claim 1, wherein the gate charging portion is further configured to provide a constant gate voltage greater than the MOSFET turn-on threshold voltage when a voltage at a capacitive load is within a predetermined percentage of a voltage of a direct current power supply.

10. A high-side MOSFET switch system comprising:
a MOSFET connected to provide power from a direct current power supply to a capacitive load; and
a gate drive circuit to provide a pulsed gate voltage to a gate of the MOSFET, the pulsed gate voltage having a first voltage for a first time period and a second voltage for a second time period, the first voltage being less than a turn-on threshold gate-source voltage of the MOSFET and the second voltage being greater than the turn-on threshold gate-source voltage,
wherein the second time period is less than a time period for a gate-source voltage of the MOSFET to exceed a second threshold voltage at which a Miller capacitance of the MOSFET is charged.

11. The high-side MOSFET switch system of claim 10, wherein the gate driver circuit comprises:
a series resistor (R2) and a shunt capacitor (C3) to establish a rise time of the MOSFET gate-source voltage at the MOSFET gate during the second time period, the shunt capacitor (C3) having a capacitance that is greater than about 10 times a gate capacitance of the MOSFET; and
a diode (D1) in parallel with the series resistor (R2), the diode (D1) to provide a discharge path for current during the first time period that facilitates a fall time of the MOSFET gate-source voltage that is less than the rise time.

12. The high-side MOSFET switch system of claim 10, further comprising a microcontroller to provide a pulsed signal to control a switch that provides the first voltage and the second voltage of the pulsed gate voltage, wherein the pulsed signal establishes a duty cycle of the second time period alternating with the first time period that is less than about 20 percent.

13. A method of pulse-driven switching of a MOSFET, the method comprising:
applying a first voltage for a first period of time to a gate of the MOSFET, the first voltage being less than a turn-on threshold voltage of the MOSFET; and
applying a second voltage for a second period of time to the MOSFET gate, the second voltage being greater than the MOSFET turn-on threshold voltage, the second period of time being less than a time period for a gate-source voltage of the MOSFET to exceed a Miller capacitance threshold,
wherein applying the first voltage alternates with applying the second voltage to provide pulse-driven switching of the MOSFET, the pulse-driven switching controlling an inrush current provided to a capacitive load by the MOSFET.

14. The method of pulse-driven switching of a MOSFET of claim 13, wherein a duty cycle of the second period of time alternating with the first period of time is less than about 20 percent.

15. The method of pulse-driven switching of a MOSFET of claim 13, wherein the MOSFET comprises a plurality of MOSFETs connected in parallel between a direct current (DC) power supply and the capacitive load.
